(19) United States
(12) Patent Application Publication
(10) Pub. No.: US 2008/0253547 A1
(43) Pub. Date: Oct. 16, 2008

(54) AUDIO CONTROL FOR TELECONFERENCING

(76) Inventors: Philipp Christian Berndt, Berlin (DE); Marc Werner Fleischmann, Foster City, CA (US)

Correspondence Address: HUGH P. GORTLER, 23 ARRIVO DRIVE, MISSION VIEJO, CA, 92692, US

(21) Appl. No.: 11/833,432

(22) Filed: Aug. 3, 2007

Related U.S. Application Data
(63) Continuation-in-part of application No. 11/735,463, filed on Apr. 14, 2007.
Application No. 11/735,463 is a continuation-in-part of application No. 11/751,152, filed on May 21, 2007.

(51) Int. Cl. H04M 3/56; H03G 5/00; H04M 3/42

(52) U.S. Cl. 379/202.01; 381/107

(57) ABSTRACT

A virtual representation includes objects that represent participants (i.e., users) in a teleconference. Volume of sound data in the teleconference is controlled according to how the users change location and relative orientation of their objects in the virtual representation.

### BRIEF DESCRIPTION OF THE DRAWINGS

FIG. 1 is an illustration of a system in accordance with an embodiment of the present invention.

FIG. 2 is an illustration of a method in accordance with an embodiment of the present invention.

FIG. 3 is an illustration of a virtual environment in accordance with an embodiment of the present invention.

FIG. 4 is an illustration of audio cut-off in accordance with an embodiment of the present invention.

FIG. 5 is an illustration of two avatars facing each other.

FIGS. 6-7 are illustrations of a method in accordance with an embodiment of the present invention.

FIG. 8 is an illustration of a system in accordance with an embodiment of the present invention.

FIG. 9 is an illustration of a method in accordance with an embodiment of the present invention.

FIG. 10 is an illustration of methods of reducing the computational burden of sound mixing in accordance with embodiments of the present invention.

FIGS. 11a-11c are illustrations of sound mixing in accordance with embodiments of the present invention.

### DETAILED DESCRIPTION

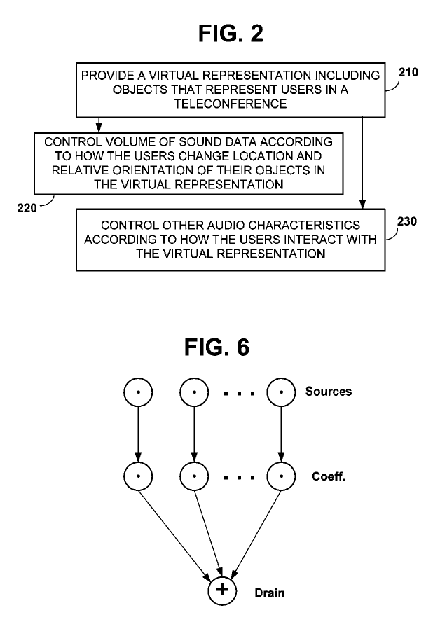

Reference is made to FIG. 2, which illustrates a method of controlling volume of sound data during a teleconference. The method includes providing a virtual representation including objects (e.g., avatars) that represent participants (i.e., users) in the teleconference (block 210), and controlling the volume of the sound data according to how the users change locations and relative orientation of their objects in the virtual representation (block 220).

In some embodiments, the users' objects have audio ranges. An audio range limits the distance that sound can be received and/or broadcasted. The audio ranges facilitate multiple teleconferences in a single virtual representation.

Audio characteristics other than volume may also be controlled according to how users interact with the virtual representation (block 230). For example, filters can be applied to sound data to add reverb, distort sounds, etc. Examples are provided below.

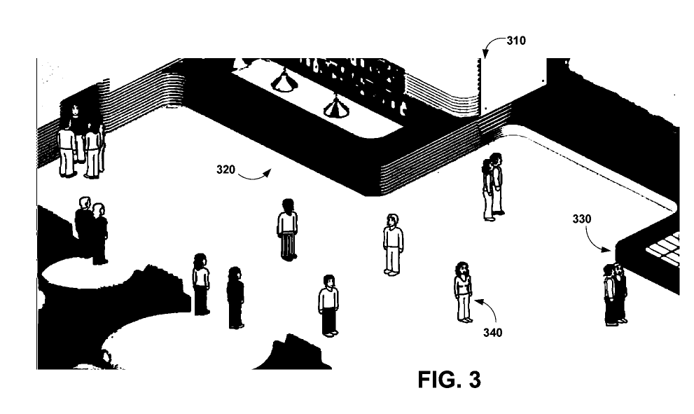

A virtual representation is not limited to any particular type. A first type of virtual representation could be similar to the visual metaphorical representations illustrated in FIGS. 3-5 and 8a-8b of Singer et al. U.S. Pat. No. 5,889,843 (a graphical user interface displays icons on a planar surface, where the icons represent audio sources).

A second type of virtual representation is a virtual environment. A virtual environment includes a scene and sounds. A virtual environment is not limited to any particular type of scene or sounds. As a first example, a virtual environment includes a beach scene with blue water, white sand and blue sky. In addition, the virtual environment includes an audio representation of a beach (e.g. waves crashing against the shore, sea gulls cries). As a second example, a virtual environment includes a club scene, complete with bar, dance floor, and dance music (an exemplary bar scene 310 is depicted in FIG. 3). As a third example, a virtual environment includes a park with a microphone and loudspeakers, where sounds picked up by the microphone are played over the speakers.

A virtual representation includes objects. An object in a virtual environment has properties that allow a user to perform certain actions on them (e.g., sit on, move, and open). An object (e.g., a Flash® object) in a virtual environment may obey certain specifications (e.g., an API).

At least some of the objects represent users of the communications system 110. These user representative objects could be images, avatars, live video, recorded sound samples, name tags, logos, user profiles, etc. In the case of avatars, live video or photos could be projected on them. The users' representative objects allow their users to see and communicate with other users in a virtual representation. In some situations, a user cannot see his own representative object, but rather sees the virtual representation as his representative object would see it (that is, from a first person perspective).

In some embodiments, the virtual representation is a virtual environment, and the users are represented by avatars. In some embodiments, volume of sound between one user and another is a function of distance between and relative orientation of their avatars. In some embodiments, the avatars also have audio ranges.

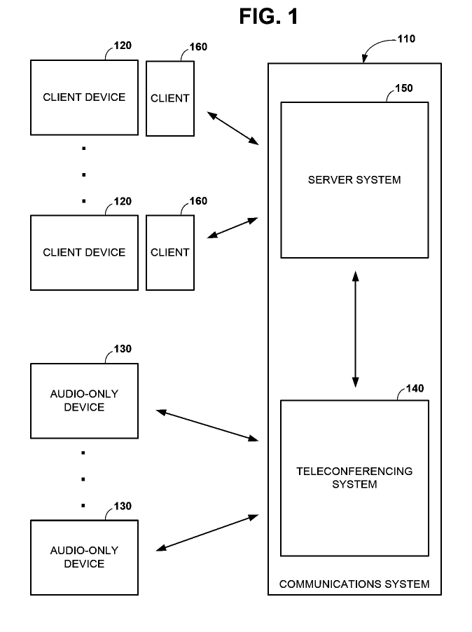

Reference is made to FIG. 1, which illustrates an exemplary communications system 110 for providing a teleconferencing service. The teleconferencing service may be provided to users having client devices 120 and audio-only devices 130. A client device 120 refers to a device that can run a client and provide a graphical interface. One example of a client is a Flash® client. Client devices 120 are not limited to any particular type. Examples of client devices 120 include, but are not limited to computers, tablet PCs, VOIP phones, gaming consoles, televisions with set-top boxes, certain cell phones, and personal digital assistants. Another example of a client device 120 is a device running a Telnet program.

Audio-only devices 130 refer to devices that provide audio but, for whatever reason, do not display a virtual representation. Examples of audio-only devices 130 include traditional phones (e.g., touch-tone phones) and VOIP phones.

A user can utilize both a client device 120 and an audio-only device 130 during a teleconference. The client device 120 is used to interact with the virtual representation and help the user enter into teleconferences. The client device 120 also interacts with the virtual representation to control volume of sound data during a teleconference. The audio-only device 130 is used to speak with at least one other user during a teleconference.

The communications system 110 includes a teleconferencing system 140 for hosting teleconferences. The teleconferencing system 140 may include a phone system for establishing phone connections with traditional phones (landline and cellular), VOIP phones, and other audio-only devices 130. For example, a user of a traditional phone can connect with the teleconferencing system 140 by placing a call to it. The teleconferencing system 140 may also include means for establishing connections with client devices 120 that have teleconferencing capability (e.g., a computer equipped with a microphone, speakers and teleconferencing software).

A teleconference is not limited to conversations between two users. A teleconference may involve many users. Moreover, the teleconferencing system 140 can host one or more teleconferences at any given time.

The communications system 110 further includes a server system 150 for providing clients 160 to those users having client devices 120. Each client 160 causes its client device 120 to display a virtual representation. A virtual representation provides a vehicle by which a user can enter into a teleconference (e.g., initiate a teleconference, join a teleconference already in progress), even if that user knows no other users represented in the virtual representation. The communications system 110 allows a user to listen in on one or more teleconferences. Even while engaged in one teleconference, a user has the ability to listen in on other teleconferences, and seamlessly leave the one teleconference and join another teleconference. A user could even be involved in a chain of teleconferences (e.g., a line of people where person C hears B and D, and person D hears C and E, and so on).

Each client 160 enables its client device 120 to move the user's representative object within the virtual representation. By moving his representative object around a virtual representation, a user can move nearby other representative objects to listen in on conversations and meet other users. By moving his representative object around a virtual environment, a user can experience the sights and sounds that the virtual environment offers.

In a virtual environment, user representative objects have states that can be changed. For instance, an avatar has states such as location and orientation. The avatar can be commanded to walk (that is, make a gradual transition) from its current location (current state) to a new location (new state).

Other objects in the virtual environment have states that can be changed. As a first example, a user can take part in a virtual volleyball game, where a volleyball is represented by an object. Hitting the volleyball causes the volleyball to follow a path towards a new location. As a second example, a balloon is represented by an object. The balloon may start uninflated (e.g., a current state) and expand gradually to a fully inflated size (new state). As a third example, an object represents a jukebox having methods (actions) such as play/stop/pause, and properties such as volume, song list, and song selection. As a fourth example, an object represents an Internet object, such as a uniform resource identifier (URI) (e.g., a web address). Clicking on the Internet object opens an Internet connection.

Different objects can provide different sounds. The sounds of a jukebox might include different songs in a playlist. The sounds of an avatar might include walking sounds. Yet even the walking sounds of different avatars might be different. For instance, the walking sound of an avatar with high heels might be different than that of one wearing flip-flop sandals.

With an object in general, one user can change its state, and other users will experience the state change. For example, one user can turn down the volume of a jukebox, and everyone represented in the virtual representation will hear the lower volume.

Additional reference is made to FIG. 3, which depicts an exemplary virtual environment including a club scene 310. The club scene 310 includes a bar 320, and dance floor 330. A user is represented by an avatar 340. Other users in the club scene 310 are represented by other avatars. An avatar could be moved from its current location to a new location by clicking on the new location in the virtual environment, pressing a key on a keyboard, entering text, entering a voice command, etc.

Dance music is projected from speakers (not shown) near the dance floor 330. As the user's avatar 340 approaches the speakers, the music heard by the user becomes louder. The music is loudest when the user's avatar 340 is in front of the speakers. As the user's avatar 340 is moved away from the speakers, the music becomes softer. If the user's avatar 340 is moved to the bar 320, the user hears background conversation (which might be actual conversations between other users at the bar 320). The user might hear other background sounds at the bar 320, such as a bartender washing glasses or mixing drinks.

An object's audio characteristics might be changed by applying filters (e.g. reverb, club acoustics) to the object's sound data. Examples for changing audio characteristics include the following. As an avatar walks from a carpeted room into a stone hall, a parameter of a reverb filter is adjusted to add more reverb to the user's voice and avatar's footsteps. As an avatar walks into a metallic chamber, a parameter of an effect filter is adjusted so the user's voice and avatar's footsteps are distorted to sound metallic. When an avatar speaks into a virtual microphone or virtual telephone, a filter (e.g. band pass filter) is applied to the avatar's sound data so the user's voice sound as if it's coming from a loudspeaker system or telephone.

The user might not know any of the other users represented in the club scene 310. However, the user can enter into a teleconference with another user by becoming voice enabled, and causing his avatar 340 to approach that other user's avatar (the users can start speaking with each other as soon as both avatars are within audio range of each other). Users can use their audio-only devices 130 to speak with each other (each audio-only device 130 makes a connection with the teleconferencing system 140, and the teleconferencing system 140 completes the connection between the audio-only devices 130). The user can command his avatar 340 to leave that teleconference, wander around the club scene 310, and approach other avatars so as to listen in on other conversations and speak with other people.

This interaction is unlike that of a conventional teleconference. In a conventional teleconference, several parties schedule a teleconference in advance. When the time comes, the participants call a number, wait for verification, and then talk. When the participants are finished talking, they hang up. In contrast, teleconferencing according to the present invention is dynamic. Multiple teleconferences might be occurring between different groups of people. The teleconferences can occur without advance planning. A user can listen in on one or more teleconferences simultaneously, enter into and leave a teleconference at will, and hop from one teleconference to another.

There are various ways in which a virtual representation can be used to control the volume of sound data during a teleconference. Examples will now be provided.

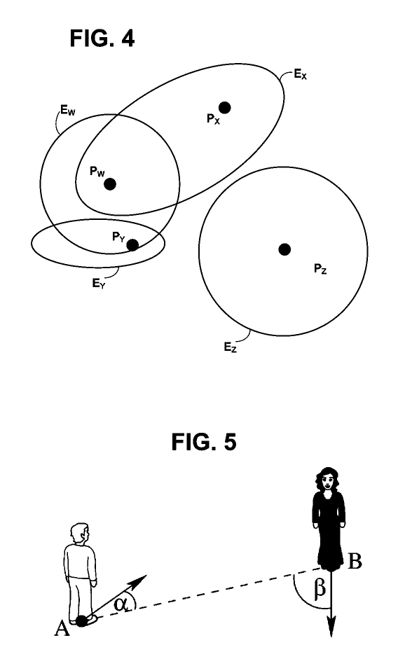

Reference is now made to FIG. 4. A user's representative object is at location P_{W} and three other objects are at locations P_{X}, P_{Y} and P_{Z}. Let MIX_{W} be the sound heard by the user represented at location P_{W}. In a simple sound model, MIX_{W} may be expressed as

MIX_{W}=aV_{X}+bV_{Y}+cV_{Z}

where V_{X}, V_{Y}, and V_{Z} are sound data from the objects at locations P_{X}, P_{Y} and P_{Z}, and where a, b and c are sound coefficients. In this simple model, the volume of sound data V_{X} is adjusted by coefficient a, the volume of sound data V_{Y} is adjusted by coefficient b, and the volume of sound data V_{Z} is adjusted by coefficient c.

The value of each coefficient may be inversely proportional to the distance between the corresponding sound source and the user's representative object. As such, sound gets louder as the user's object and the sound source move closer together, and sound gets softer as they move farther apart. The server system generates the sound coefficients. However, the volume control is not limited to a topology metric such as distance. That is, closeness of two objects is not limited to distance.

Each object may have an audio range. The audio range is used to determine whether sound is cut off. The audio ranges of the objects at locations P_{W} and P_{Z} are indicated by circles E_{W} and E_{Z}. Audio ranges of the representations at locations P_{X} and P_{Y} are indicated by ellipses E_{X} and E_{Y}. The elliptical shape of an audio range indicates that the sound from its audio source is directional or asymmetric. The circular shape indicates sound that the sound is omni-directional (that is, projected equally in all directions).

In some embodiments, coefficient c=0 when location P_{Z} is outside the range E_{W}, and coefficients a=1 and b=1 when locations P_{X} and P_{Y} are within the range E_{W}. In other embodiments, a coefficient may vary between 0 and 1. For instance, a coefficient might equal a value of zero at the perimeter of the range, a value of one at the location of the user's representative object, and a fractional value therebetween.

In some embodiments, topology metrics might be used in combination with the audio range. For example, a sound will fade as the distance between the source and the user's representative object increases, and the sound will be cut off as soon as the sound source is out of range.

The audio range may be a receiving range or a broadcasting range. If a receiving range, a user will hear other sources within that range. Thus, the user will hear other users whose representative objects are at locations P_{X} and P_{Y}, since the audio ranges Eₓ and E_{Y} intersect the range E_{W}. The user will not hear another whose representative object is at location P_{Z}, since the audio range E_{W} does not intersect the range E_{Z}.

If the audio range is a broadcasting range, a user hears those sources in whose broadcasting range he is. Thus, the user will hear the user whose representative object is at location P_{X}, since location P_{W} is within the ellipse E_{X}. The user will not hear those users whose representative objects are at locations P_{Y} and P_{Z}, since the location P_{W} is outside of the ellipses E_{Y} and E_{Z}.

In some embodiments, the user's audio range is fixed. In other embodiments, the user's audio range can be dynamically adjusted. For instance, the audio range can be reduced if a virtual environment becomes too crowded. Some embodiments might have a function that allows for private conversations. That function may be realized by reducing the audio range (e.g. to a whisper) or by forming a disconnected “sound bubble.” Some embodiments might have a “do not disturb” function, which may be realized by reducing the audio range to zero.

As for objects representing users, avatars offer certain advantages over other types of objects. Avatars allow one user to interact with another.

One type of interaction is realized by the orientation of two avatars. For instance, the volume of sound between two users may be a function of relative orientation of the two avatars. Two users whose avatars are facing each other will hear each other better than they would if one avatar is facing away from the other, and much better than if the two avatars are facing in different directions.

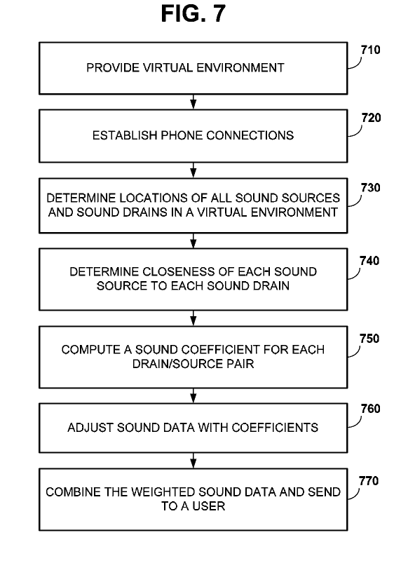

Reference is made to FIG. 5, which shows two avatars A and B facing in the directions of the arrows. The avatars A and B are facing each other directly if angles α and β between the avatars' attitude and their connecting line AB equal zero. Assume avatar A is speaking and avatar B is listening. The value of the attenuation function can vary differently for changes to α and β. In this case the attenuation is asymmetrical. One advantage of orientation-based attenuation is allowing a user to take part in one conversation, while casually hearing other conversations.

The attenuation may also be a function of the distance between avatars A and B. The distance between avatars A and B may be taken along line AB.

A sound model may be based on direction, orientation, distance and states of the objects associated with the sound sources and sound drains. Let V_{d w}(t) be the sound heard by the user represented by the object at location P_{w} and associated with sound drain w. In such a model, V_{d w}(t) may be expressed as

$${V}_{dw} ( t ) = {vol}_{{d}_{w}} \cdot {\sum }_{n = 1}^{{s}_{max}} {c}_{wn} \cdot {V}_{{s}_{n}} ( t )$$

with

c_{wn}=volₛ_{ₙ}·ƒ_{wn}(d_{nw},α_{nw},β_{nw},uₙ,u_{w})

where
vol_{d}_{_{w}} is the drain gain of sound drain w,
sₘₐₓ is the total number of sound sources in the environment,
Vₛ_{ₙ}(t) is the sound produced by sound source n,
volₛ_{ₙ} is the source gain of sound source n,
ƒ_{wn}(d_{nw},α_{nw},β_{nw},uₙ,u_{w}) is an attenuation function determining how source n is attenuated for drain w,
d_{nw} is the distance between w and n,
α_{nw} is the angle between the sound emission direction (speaking direction) and the connecting line of user w and sound source n, and
β_{nw} is the angle between the connecting line of user w and sound source n and the sound reception direction (hearing direction),
uₙ is the state of the object associated with sound source n, and
U_{w} is the state of the object associated with sound drain w.

The state uₙ of the object associated with sound source n reflects any other factor or set of factors that influence the volume of sound from the sound source n. For instance, the state uₙ might reduce the volume if the object associated with sound source n is in a whisper mode, or it might increase the volume if the object associated with sound source n is in a yell mode. Similarly, the state of the object u_{w} associated with sound drain w reflects any other factor or set of factors that influence the volume of sound heard by the sound drain w. For instance, the state u_{w} could reduce the volume of the sound heard by the sound drain w if the object associated with sound drain w is in a do-not-disturb mode.

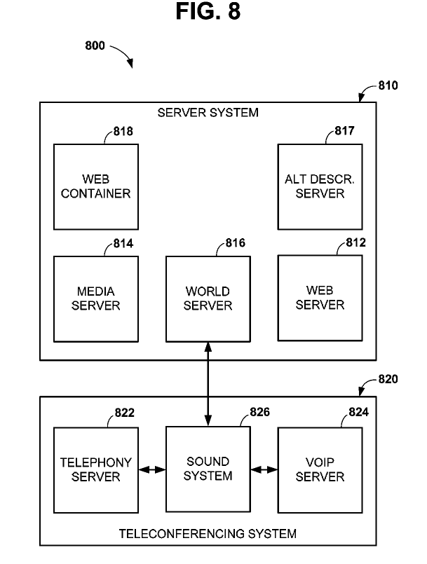

Reference is made to FIGS. 6 and 7, which illustrate a first approach for controlling the volume of sound data in a teleconference. The server system generates sound coefficients, and the teleconferencing system uses the sound coefficients to vary the audio characteristics (e.g., audio volume) of sound data that goes from sound sources to a sound drain. A sound drain refers to the representative object of a user who can hear sounds in the virtual environment. A sound coefficient can vary the audio volume or other audio characteristics as a function of closeness of a sound source and a sound drain.

A virtual environment is provided (block 710), and phone connections are established with a plurality of users (block 720). The users are represented by objects in the virtual environment. Each user representative object can be both sound drain and sound source.

At block 730, locations of all sound sources and sound drains in the virtual environment are determined. Sound sources include objects that can provide sound in a virtual environment (e.g., a jukebox, speakers, a running stream of water, users' representative objects). A sound source could be multimedia from an Internet connection (e.g., audio from a YouTube video).

The following functions are performed for each sound drain in the virtual environment. At block 740, closeness of each sound source to a drain is determined. This function is performed for each sound drain in the virtual environment. The server system can perform this function, since it keeps track of the object states.

At block 750, a coefficient for each drain/source pair is computed. Each coefficient varies the volume of sound from a source as a function of its closeness to the drain. The closeness is not limited to distance. This function may also be performed by the server system, since it maintains information about closeness of the objects. The server system supplies the sound coefficients to the teleconferencing system.

The sound from a source to a drain can be cut off (that is, not heard) if the drain is outside of an audio range of the source (in the case of a broadcasting range). The sound coefficient would reflect such cut-off (e.g., by being set to zero or close to zero). The server system can determine the range, and whether cut-off occurs, since it manages the object states.

At block 760, sound data from each sound source is adjusted with its corresponding coefficient. As a result, the sound data from the sound sources are weighted as a function of closeness to a drain.

At block 770, the weighted sound data is combined and sent back on a phone line or VOIP channel to a user. Thus, an auditory environment is synthesized from the sounds of different objects, and the synthesized environment is heard by the user.

The process at blocks 730-750 is performed continuously, since locations, orientations and other states in the virtual representation are changed continuously. The process at blocks 760-770 is also performed continuously, as the sound data is streamed continuously (e.g., in chunks of 100 ms).

Consider a virtual environment in which there are n sound sources for each of n drains. The computation effort for mixing sound data from all n sources for each drain will be in the order of n² (i.e., O(n²)). This can pose a large scaling problem, especially for large teleconferences and dense crowds.

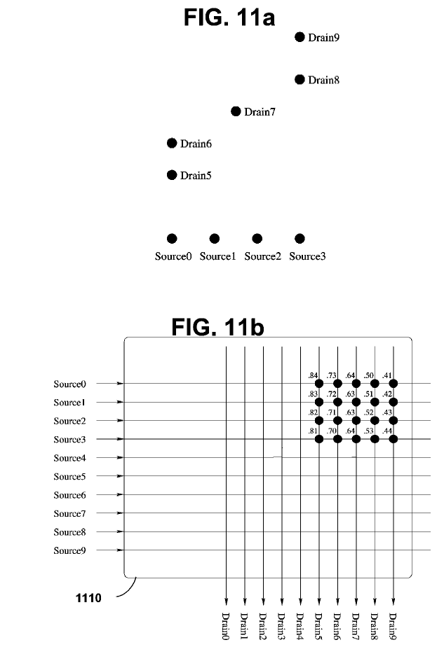

Reference is now made to FIG. 10. Any of the following approaches, alone or in combination, could be used to reduce the computation burden.

At block 1010, for each drain, the sound data is mixed only for those sound sources making a significant contribution. As a first example, the subset includes the loudest sound sources (i.e., those with the highest coefficients). As a second example, the subset includes only those representative objects whose users are actually talking.

As a third example, sound sources that are not active (i.e., sound sources that are not providing sound data) are excluded. If a user's object is not voice-enabled, it can be excluded. If a play feature of a jukebox is off, the jukebox can be excluded.

At block 1008, audio ranges of certain objects may be automatically set at or near zero, so that their coefficients are set at or near zero. The sound data from these objects would be excluded at block 1010.

At block 1020, a minimum distance between objects may be enforced. This policy would prevent users from forming dense crowds.

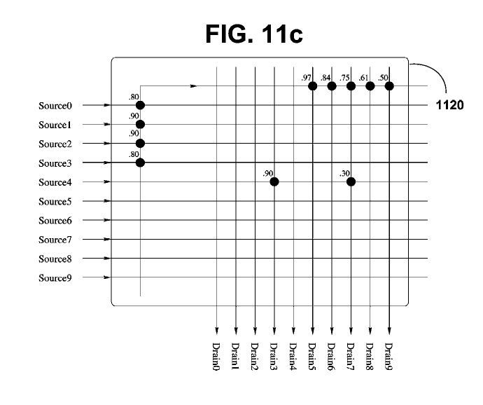

At block 1030, the teleconferencing system could also premix sound data for groups of sound sources. The premixed sound data of a group could be mixed with other audio data for a sound drain. An example of premixing is illustrated in FIG. 11c.

At block 1040, in addition to or instead of sound mixing illustrated in FIGS. 6 and 7 (that is, instead of generating a synthesized environment), the teleconferencing system could make direct connections between a source and a drain. This might be done if the server system determines that two users can essentially only hear each other. Making direct connections can preserve computing power and decrease latencies.

Reference is now made to FIG. 11a, which shows a line of sound sources (Source0 to Source3) and five objects (Drain5 to Drain9) listening to those sound sources. The five drains (Drain5 to Drain 9) are in different positions with respect to the line of sound sources.

FIG. 11b illustrates a sound mixer 1110 that mixes sound data from the line of sources (Source0 to Source3) without premixing. Each sound source (Source0 to Source3) has a coefficient for each sound drain (the coefficients are represented by filled circles and exemplary values are also provided). The sound mixer 1110 performs four mixing operations per sound drain for a total of 20 mixing operations.

FIG. 11c illustrates an alternative sound mixer 1120, which premixes the sound data from the line of sources (Source0 to Source3). The sound sources (Source0 to Source3) are grouped, and the sound mixer 1120 mixes the sound data from the group. Four mixing operations are performed during premixing.

The sound mixer 1120 computes a single coefficient for each drain and performs one mixing operation per drain. The value of a coefficient may be a function of distance from its drain to the group (e.g., distance from a drain to a centroid of the group). Thus, the sound mixer 1120 performs an additional five mixing operations for a total of nine mixing operations.

The coefficients that premix sound data into a single sound source for a group could be determined with respect to a certain point such as a centroid (such coefficients are indicated by values 0.8, 0.9, 0.9, and 0.8), or some other metric. Alternatively, the values could all be set to one, which means that each drain would hear the same volume from each sound source (Source0-Source3). However, different drains would still hear different volumes from the group (as indicated by the different coefficients 0.97, 0.84, 0.75, 0.61 and 0.50).

Sound sources may be grouped in a way that minimizes the mixing operations, yet keeps the deviation from the ideal sound (that is, sound without pre-mixing) at an acceptable level. Various clustering algorithms can be used to group the sound sources (e.g., a K-means algorithm; or by iteratively clustering the mutual nearest neighbors).

Additional sources can be mixed without premixing. FIG. 11c illustrates a fifth sound source (Source4) that is not grouped with the line of sound sources. The fifth sound source is assigned its own coefficients for Drain3 and Drain7. Thus, a single mixing operation is performed for Drain3, and two mixing operations are performed for Drain7.

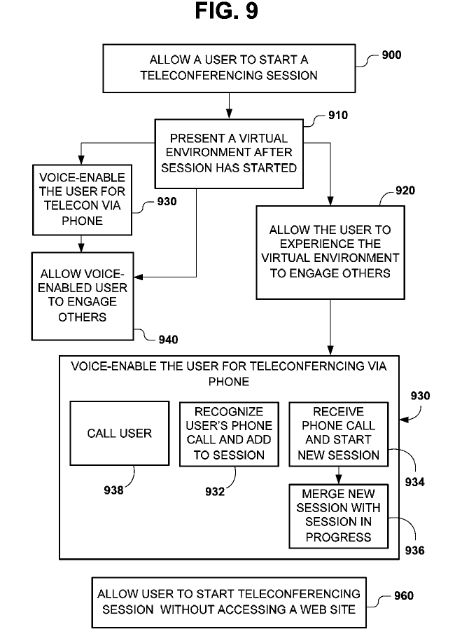

Reference is made to FIG. 8, which illustrates an exemplary web-based communications system 800. The communications system 400 includes a VE server system 810. The “VE” refers to virtual environment.

The VE server system 810 hosts a website, which includes a collection of web pages, images, videos and other digital assets. The VE server system 810 includes a web server 812 for serving web pages, and a media server 814 for storing video, images, and other digital assets.

One or more of the web pages embed client files. Files for a Flash® client, for instance, are made up of several separate Flash® objects (.swf files) that are served by the web server 812 (some of which can be loaded dynamically when they are needed).

A client is not limited to a Flash® client. Other browser-based clients include, without limitation, Java™ applets, Microsoft® Silverlight™ clients, .NET applets, Shockwave® clients, scripts such as JavaScript, etc. A downloadable, installable program could even be used.

Using a web browser, a client device downloads web pages from the web server 812 and then downloads the embedded client files from the web server 812. The client files are loaded into the client device, and the client is started. The client starts running the client files and loads the remaining parts of the client files (if any) from the web server 812.

An entire client or a portion thereof may be provided to a client device. Consider the example of a Flash® client including a Flash® player and one or more Flash® objects The Flash® player is already installed on a client device. When .swf files are sent to and loaded into the Flash® player, the Flash® player causes the client device to display a virtual environment. The client also accepts inputs (e.g., keyboard inputs, mouse inputs) that command a user's representative object to move about and experience the virtual environment.

The server system 810 also includes a world server 816. The “world” refers to all virtual representations provided by the server system 810. When a client starts running, it opens a connection with the world server 816. The server system 810 selects a description of a virtual environment and sends the selected description to the client. The selected description contains links to graphics and other media for the virtual environment. The description also contains coordinates and appearances of all objects in the virtual environment. The client loads media (e.g., images) from the media server 814, and projects the images (e.g., in isometric, 3-D).

The client displays objects in the virtual environment. Some of these objects are user representative objects such as avatars. The animated views of an object could comprise pre-rendered images or just-in-time rendered 3D-Models and textures, that is, objects could be loaded as individual Shockwave® objects, parameterized generic Shockwave® objects, images, movies, 3D-Models optionally including textures, and animations. Users could have unique/personal avatars or share generic avatars.

When a client device wants an object to move to a new location in the virtual environment, its client determines the coordinates of the new location and a desired time to start moving the object, and generates a request. The request is sent to the world server 816.

The world server 816 receives a request and updates the data structure representing the “world.” The world server 816 manages each object state in one or more virtual environments, and updates the states that change. Examples of states include avatar state, objects they're carrying, user state (account, permissions, rights, audio range, etc.), and call management. When a user commands an object in a virtual environment to a new state, the world server 816 commands all clients represented in the virtual environment to transition the state of that object, so client devices display the object at roughly the same state at roughly the same time.

The world server 816 can also manage objects that transition gradually or abruptly. When a client device commands an object to transition to a new state, the world server 816 receives the command and generates an event that causes all of the clients to show the object at the new state at a specified time.

The communications system 800 also includes a teleconferencing system 820. Some embodiments of the teleconferencing system 820 may include a telephony server 822 for establishing calls with traditional telephones. For instance, the telephony server 822 may include PBX or ISDN cards for making connections for users with traditional telephones (e.g., touch-tone phones) and digital phones. The telephony server 822 may include mobile network or analog network connectors. The cards act as the terminal side of a PBX or ISDN line and, in cooperation with associated software perform all low-level signaling for establishing phone connections. Events (e.g. ringing, connect, disconnect) and audio data in chunks (of e.g. 100 ms) are passed from a card to a sound system 826. The sound system 826, among other things, mixes the audio between users in a teleconference, mixes any external sounds (e.g., the sound of a jukebox, a person walking, etc) and passes the mixed (drain) chunks back to the card and, therefore, to a user.

Some embodiments of the teleconferencing system 820 may transcode calls into VOIP, or receive VOIP streams directly from third parties (e.g., telecommunication companies). In those embodiments, events would originate not from the cards, but transparently from an IP network.

Some embodiments of the teleconferencing system 820 may include a VOIP server 824 for establishing connections with users who call in with VOIP phones. In this case, a client (e.g., the client 160 of FIG. 1) may contain functionality by which it tries to connect to a VOIP soft-phone audio-only device using, for example, an xml-socket connection. If the client detects the VOIP phone, it enables VOIP functionality for the user. The user can then (e.g., by the click of a button) cause the client to establish a connection by issuing a CALL command via the socket to the VOIP phone which calls the VOIP server 824 while including information necessary to authenticate the VOIP connection.

The world server 816 associates each authenticated VOIP connection with a client connection. The world server 416 associates each authenticated PBX connection with a client connection.

For devices that are enabled to run Telnet sessions, a user could establish a Telnet session to receive information, questions and options, and also to enter commands. For Telnet-enabled devices, the means 817 could provide a written description of a virtual environment.

The telephony system 822 can also allow users of audio-only devices to control objects in a virtual environment. A user with only an audio-only device alone can experience sounds of the virtual environment as well as speak with others, but cannot see sights of the virtual environment. The telephony system 822 can use phone signals (e.g., DTMF, voice commands) from phones to control the actions of their corresponding representation in the virtual environment.

The audio-only device generates signals for selecting and controlling objects in the virtual representation, and the telephony system 822 translates the signals and informs the server system to take action, such as changing the state of an object. As examples, the signals may be dial tone (DTMF) signals, voice signals, or some other type of phone signal. Consider a touch tone phone. Certain buttons on the phone can correspond to commands. A user with a touch phone or DTMF-enabled VOIP phone can execute a command by entering that command using DTMF tones. Each command can be supplied with one or more arguments. An argument could be a phone number or other number sequence. In some embodiments, voice commands could be interpreted and used.

The server system can also include a means 817 for providing an audio description of the virtual environment. For example, a virtual environment can be described to a user from the perspective of the user's avatar. Objects that are closer to the user's avatar might be described in greater detail. The description may include or leave out detail to keep the overall length of the description approximately constant. The user can request more detailed descriptions of certain objects, upon which additional details are revealed. The server system can also generate an audio description of options in response to a command. The teleconferencing system mixes the audio description (if any) and other audio, and supplies the mixed sound data to the user's audio-only device.

A sound system 826 can play sound clips, such as sounds in the virtual environment. The sound clips are synchronized with state changes of the objects in the virtual environment. The sound system 826 starts and stops the sound clips at the state transition start and stop times indicated by the world server 816.

The sound system 826 can mix sounds of the virtual environment with audio from the teleconferencing. Sound mixing is not limited to any particular approach, and may be performed as described above. The teleconferencing system may receive a list of patches, sets of coefficients, and goes through the list. The teleconferencing system can also use heuristics to determine whether it has enough time to patch all connections. If not enough time is available, packets are dropped.

The VE server system 810 may also include one or more servers that offer additional services. For example, a web container 818 might be used to implement servlet and JavaServer Pages (JSP) specifications to provide an environment for Java code to run in cooperation with the web server 812.

All servers in the communications system 800 can be run on the same machine, or distributed over different machines. Communication may be performed by a remote invocation call. For example, an HTTP or HTTPS-based protocol (e.g. SOAP) can be used by the server(s) and network-connected devices to transport the clients and communicate with the clients.

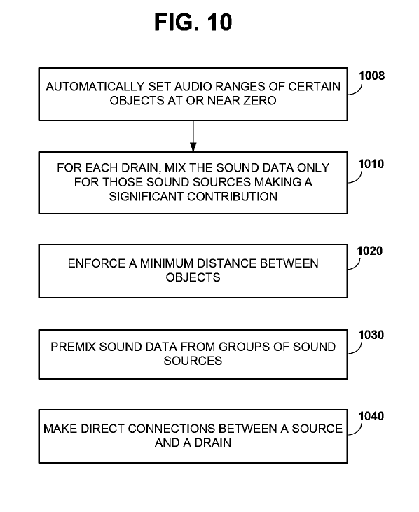

Reference is now made to FIG. 9, which illustrates an example of using the communications system 800. At block 900, a user is allowed to start a teleconferencing session. For example, using a web browser, a user enters a web site, and logs into a teleconferencing service. The provider of the communications service starts the teleconferencing session.

After the session is started, a virtual environment is presented to the user (block 910). If, for example, the service provider runs a web site, a web browser can download and display a virtual environment to the user.

A user can control its representative object to move around a virtual environment to experience the different sights and sounds that the virtual environment provides (block 920). For instance, a representative object could turn on a jukebox and select songs from a playlist. The jukebox would play the selected songs.

A user can also move its representative object around a virtual environment to engage other users represented in the virtual representation (block 920). The user's representative object may be moved by clicking on a location in the virtual environment, pressing a key on a keyboard, pressing a key on a telephone, entering text, entering a voice command, etc.

There are various ways in which the user can engage others in the virtual environment. One way is by wandering around the virtual environment and hearing conversations that are already in progress. As the user moves its representative object around the virtual environment, that user can hear voices and other sounds.

The user can then participate in a conversation by becoming voice-enabled via phone (block 930). Becoming voice-enabled allows the user to speak with others who are voice-enabled. For example, the user wants to have a teleconference using a phone. The phone could be a traditional phone or a VOIP phone. To enter into a teleconference, the user uses the phone to call the communications system 110. Using a traditional telephone, the user can call the virtual environment that he is in (e.g., by calling a unique phone number, or by calling a general number and entering additional data such as user ID and PIN, via DTMF). Using a VolP phone, a user could call a virtual environment by calling its unique VolP address.

The service provider can join the phone call with the session in progress if it can recognize the user's phone number (block 932). If the service provider cannot recognize the user's phone number, the user starts a new session via the phone (block 934), the user identifies himself (e.g., by entering additional data such as a user ID and PIN via DTMF) and then the service provider merges the new phone session with the session already in progress (block 936). Instead of the user calling the service provider, the user can request the service provider to call the user (block 938).

Once voice-enabled (block 930), the user can use a phone to talk to others who are voice-enabled. Once voice-enabled (block 930), the user remains voice-enabled until the user discontinues the call (e.g., hangs up the phone).

In some embodiments, the communications system allows a user to log into the teleconferencing service and enter into a teleconference without accessing the web site (block 960). A user might only have access to a touch-tone telephone or other audio-only device 130 that can't display a virtual environment. Consider a traditional telephone. With only the telephone, the user can call a telephone number and connect to the service provider. The service provider can then add the user's representative object to the virtual environment. Via telephone signals (e.g., DTMF, voice control), the user can move its representative object about the virtual environment, listen to other conversations, meet other people and experience the sounds (but not sights) of the virtual environment. Although the user cannot see its representative objects, others viewing the virtual environment can see the user's representative object.

1. A method of controlling volume of sound data during a teleconference, the method comprising providing a virtual representation including objects that represent users in the teleconference; and controlling the volume of the sound data according to how the users change location and relative orientation of their objects in the virtual representation.

2. The method of claim 1, further comprising changing other audio characteristics of the sound data according to how the users interact with the virtual representation.

3. The method of claim 1, wherein objects in the virtual representation also have audio ranges, whereby the volume of the sound data is also controlled according to the audio ranges.

4. The method of claim 3, wherein the audio ranges are adjustable.

5. The method of claim 1, wherein the virtual representation is a virtual environment; and wherein the users are represented by avatars.

6. The method of claim 5, wherein volume of sound data between two users is a function of relative orientation of their avatars.

7. The method of claim 1, wherein the virtual representation is provided by a server system that computes a sound coefficient for each object that is a sound source with respect to a drain; and wherein for each user, controlling the volume includes applying those sound coefficients to the sound data of their corresponding objects, mixing the modified sound data and supplying the mixed sound data to the drain.

8. The method of claim 7, wherein the sound data is mixed according to
$${V}_{dw} ( t ) = {vol}_{{d}_{w}} \cdot {\sum }_{n = 1}^{{s}_{max}} {c}_{wn} \cdot {V}_{{s}_{n}} ( t ) .$$

9. A method comprising:
providing a virtual representation;
establishing phone connections with a plurality of users, the users represented by objects in the virtual representation, each user representative object being both sound drain and sound source; and
for each drain, mixing sound data from different sound sources and providing the mixed data to the user associated with the drain, where volume of sound data from a source is adjusted according to a topology metric of the source with respect to the drain;
whereby the users are not directly connected, but instead communicate through a synthesized auditory environment.

10. The method of claim 9, wherein mixing the sound data for each drain includes
computing audio parameters for each paired source, each audio parameter controlling sound volume as a function of closeness of its corresponding source to the drain; and
adjusting sound data of each paired source with the corresponding audio parameter, mixing the adjusted sound data of the paired sources, and providing the mixed sound data to the user associated with the drain.

11. The method of claim 9, wherein the virtual representation includes other objects that are sound sources, where volume of sound data from a source is adjusted according to a topology metric of the source with respect to the drain; and wherein adjusted sound data from the other objects is also mixed and supplied to the drain.

12. The method of claim 9, wherein the objects include audio ranges.

13. The method of claim 9, wherein the topology metric is virtual distance between a source and a drain.

14. The method of claim 9, wherein the topology metric includes distance and orientation.

15. The method of claim 9, whereby audio is clustered to reduce computational burden.

16. The method of claim 9, wherein sound is mixed according to
$${V}_{dw} ( t ) = {vol}_{{d}_{w}} \cdot {\sum }_{n = 1}^{{s}_{max}} {c}_{wn} \cdot {V}_{{s}_{n}} ( t ) .$$

17. The method of claim 9, wherein to reduce the computation burden of mixing the sound data for each drain, the sound data is mixed only for those sound sources making a significant contribution.

18. The method of claim 17, wherein audio ranges of certain objects are automatically set at or near zero, whereby the sound data of those certain objects are excluded from the mixing.

19. The method of claim 9, wherein a minimum distance between objects is imposed to reduce the computation burden of mixing the sound data.

20. The method of claim 9, wherein at least some sound data is premixed to reduce the computation burden of mixing the sound data; wherein the premixing includes mixing sound data from a group of sound drains and assigning a single coefficient per drain to the group.

21. The method of claim 9, wherein direct connections are made between a source and a drain to reduce the computation burden of mixing the sound data.

22. A communications system comprising:
phone-based teleconferencing means; and
means for providing a virtual representation including objects that represent participants in a teleconference, the virtual representation allowing participants to use the phone-based teleconferencing means to enter into teleconferences and to control volume during the teleconferences, the volume controlled according to how the users change location and relative orientation of their objects in the virtual representation.

23. A communications system comprising:
a server system for providing a virtual representation; and
a teleconferencing system for establishing phone connections with a plurality of users, the users represented by objects in the virtual representation,
the teleconferencing system controlling volume during a teleconference according to how the users change location and relative orientation of their representative objects in the virtual representation.

24. The system of claim 23, wherein each user representative object is both sound drain and sound source; and wherein for each drain, mixing sound data from different sound sources and providing the mixed data to the user associated with the drain, where volume of sound data from a source is adjusted according to a topology metric of the source with respect to the drain.
